(19) United States
(12) Patent Application Publication
(10) Pub. No.: US 2021/0098503 A1
(43) Pub. Date: Apr. 1, 2021

(54) ARRAY SUBSTRATE, PREPARATION METHOD THEREOF AND DISPLAY PANEL

(71) Applicants: Chengdu BOE Optoelectronics Technology Co., Ltd., Chengdu (CN); BOE Technology Group Co., Ltd., Beijing (CN)

(72) Inventors: Xiaoqi Ding, Beijing (CN); Peng Huang, Beijing (CN); Guoyi Cui, Beijing (CN); Tao Gao, Beijing (CN); Li Jia, Beijing (CN); Zeliang Li, Beijing (CN); Ke Liu, Beijing (CN)

(73) Assignees: Chengdu BOE Optoelectronics Technology Co., Ltd.; BOE Technology Group Co., Ltd.

(21) Appl. No.: 17/007,477

(22) Filed: Aug. 31, 2020

(30) Foreign Application Priority Data
Sep. 26, 2019 (CN) 201910917664.7

(51) Int. Cl. H01L 27/12

(52) U.S. Cl. CPC H01L 27/1222; H01L 27/1251; H01L 27/127

(57) ABSTRACT

A method for preparing an array substrate includes: forming first and second active layers, and first and second gate layers above a base substrate; forming first and second via holes for exposing the first active layer and etching the first active layer; forming a first source-drain electrode layer including a first source electrode layer contacting the first active layer through the first via hole and a first drain electrode layer contacting the first active layer through the second via hole; forming third and fourth via holes for exposing the second active layer; forming a second source-drain electrode layer including a second source electrode layer contacting the second active layer through the third via hole and a second drain electrode layer contacting the second active layer through the fourth via hole. The second source/drain electrode layer is electrically connected with the first source-drain electrode layer.

### CROSS-REFERENCE TO RELATED APPLICATION

This application is based on and claims priority under 35 U.S.C 119 to Chinese Patent Application No. 201910917664.7, filed on Sep. 26, 2019, in the China National Intellectual Property Administration. The entire disclosure of the above application is incorporated herein by reference.

### FIELD

The present disclosure relates to the technical field of display and in particular to an array substrate, a preparation method thereof and a display panel.

### BACKGROUND

A low temperature polycrystalline oxide (LTPO) thin film transistor (TFT) technology is regarded as a new technology capable of reducing the power consumption of a mobile device due to the combination of the advantages of higher electron mobility and stability of low temperature poly-silicon (LTPS) and the advantages of good uniformity and less electric leakage of an oxide TFT. An LTPO display product may achieve a larger image with the same power consumption so as to more conform to the tendency of a large-sized full screen.

### SUMMARY

Embodiments of the present disclosure provide a method for preparing an array substrate, including:

forming a first active layer and a first gate layer of a low temperature poly-silicon (LTPS) thin film transistor (TFT) as well as a second active layer and a second gate layer of an oxide TFT above a base substrate;

forming a first via hole and a second via hole for exposing the first active layer, and etching the first active layer in the first via hole and the second via hole by a buffered oxide etch (BOE) process;

forming a first source-drain electrode layer of the LTPS TFT, wherein the first source-drain electrode layer includes a first source electrode layer in contact with the first active layer through the first via hole, and a first drain electrode layer in contact with the first active layer through the second via hole;

forming a third via hole and a fourth via hole for exposing the second active layer; and

forming a second source-drain electrode layer of the oxide TFT, wherein the second source-drain electrode layer includes a second source electrode layer in contact with the second active layer through the third via hole and a second drain electrode layer in contact with the second active layer through the fourth via hole, and the second source electrode layer or the second drain electrode layer is electrically connected with the first source-drain electrode layer.

Optionally, the forming a first active layer and a first gate layer of a LTPS TFT as well as a second active layer and a second gate layer of an oxide TFT above a base substrate includes:

sequentially forming a pattern of the first active layer, a first gate insulator, a pattern of the first gate layer and a first interlayer dielectric layer above the base substrate; and

sequentially forming a pattern of the second active layer, a pattern of a second gate insulator, a pattern of the second gate layer and a second interlayer dielectric layer above the first interlayer dielectric layer.

Optionally, the forming a first via hole and a second via hole for exposing the first active layer includes:

forming the first via hole and the second via hole for exposing the first active layer in the second interlayer dielectric layer, the first interlayer dielectric layer and the first gate insulator.

Optionally, after forming the first source-drain electrode layer, the method further includes:

depositing a protective layer on an overall surface; and

forming a first planarization layer on the protective layer.

Optionally, the forming a third via hole and a fourth via hole for exposing the second active layer specifically includes:

forming the third via hole and the fourth via hole for exposing the second active layer in the first planarization layer, the protective layer and the second interlayer dielectric layer.

Optionally, when forming the third via hole and the fourth via hole for exposing the second active layer, the method further includes:

forming a fifth via hole and a sixth via hole for exposing the first source-drain electrode layer in the first planarization layer and the protective layer.

Optionally, the forming the second source-drain electrode layer includes:

forming the second source electrode layer in contact with the second active layer through the third via hole, forming the second drain electrode layer in contact with the second active layer through the fourth via hole, and forming a connecting lead layer in contact with the first source-drain electrode layer through the sixth via hole, wherein the second source electrode layer or the second drain electrode layer extends to be in contact with the first source-drain electrode layer through the fifth via hole.

Embodiments of the present application provide an array substrate prepared by adopting the above-mentioned method for preparing the array substrate, provided by embodiments of the present application.

The array substrate includes a LTPS TFT and an oxide TFT electrically connected with the LTPS TFT.

The LTPS TFT includes a first active layer, a first gate layer and a first source-drain electrode layer. The first source-drain electrode layer includes a first source electrode layer in contact with the first active layer through a first via hole and a first drain electrode layer in contact with the first active layer through a second via hole.

The oxide thin film transistor includes a second active layer, a second gate layer and a second source-drain electrode layer. The second source-drain electrode layer includes a second source electrode layer in contact with the second active layer through a third via hole and a second drain electrode layer in contact with the second active layer through a fourth via hole, and the second source electrode layer or the second drain electrode layer is electrically connected with the first source-drain electrode layer.

Optionally, the array substrate further includes a protective layer on the first source-drain electrode layer, a first planarization layer on the protective layer and a connecting lead layer arranged on the same layer with the second source-drain electrode layer. The protective layer and the first planarization layer include a fifth via hole and a sixth via hole for exposing the first source-drain electrode layer, the second source electrode layer or the second drain electrode layer extends to be in contact with the first source-drain electrode layer through the fifth via hole, and the connecting lead layer is in contact with the first source-drain electrode layer through the sixth via hole.

Embodiments of the present disclosure provide a display panel including the above-mentioned array substrate provided by embodiments of the present application.

### BRIEF DESCRIPTION OF THE DRAWINGS

To describe technical solutions in embodiments of the present disclosure more clearly, the accompanying drawings required for describing the embodiments are briefly introduced below. Apparently, the accompanying drawings in the following description show only some embodiments of the present disclosure, and those of ordinary skill in the art may still acquire other accompanying drawings from these accompanying drawings without creative efforts.

FIG. 1 is a schematic diagram of a method for preparing an array substrate, provided by an embodiment of the present application;

FIG. 2A is a first schematic structural diagram in a process of preparing an array substrate, provided by an embodiment of the present application;

FIG. 2B is a second schematic structural diagram in a process of preparing an array substrate, provided by an embodiment of the present application;

FIG. 2C is a third schematic structural diagram in a process of preparing an array substrate, provided by an embodiment of the present application;

FIG. 2D is a fourth schematic structural diagram in a process of preparing an array substrate, provided by an embodiment of the present application;

FIG. 2E is a fifth schematic structural diagram in a process of preparing an array substrate, provided by an embodiment of the present application;

FIG. 2F is a sixth schematic structural diagram in a process of preparing an array substrate, provided by an embodiment of the present application; and

FIG. 3 is a schematic structural diagram of an array substrate prepared by using a method for preparing the array substrate, provided by an embodiment of the present application.

### DETAILED DESCRIPTION OF THE EMBODIMENTS

A preparation process of the LTPO in the related art includes: firstly, etching a hole for exposing an indium gallium zinc oxide (IGZO) active layer; next, forming a metal layer serving as a source-drain electrode layer of the oxide TFT; then, etching a via hole for exposing an LTPS active layer, and completing a buffered oxide etch (BOE) process; and then, forming a source-drain electrode layer of an LTPS TFT, and performing lap joint on the source-drain electrode layer of the LTPS TFT and the source-drain electrode layer of the Oxide TFT.

A BOE solution is required to be used in the BOE process, the BOE solution may permeate into the IGZO active layer even if the IGZO active layer in a via hole area is covered with the metal layer due to the poor covering effect of the metal layer, and thus, IGZO crack is caused to result in the failure of a TFT device.

In conclusion, in the preparation process of the LTPO in the related art, an oxide active layer is easily affected by the BOE solution to cause crack so as to result in the failure of the TFT device and thus, the yield of products is affected greatly.

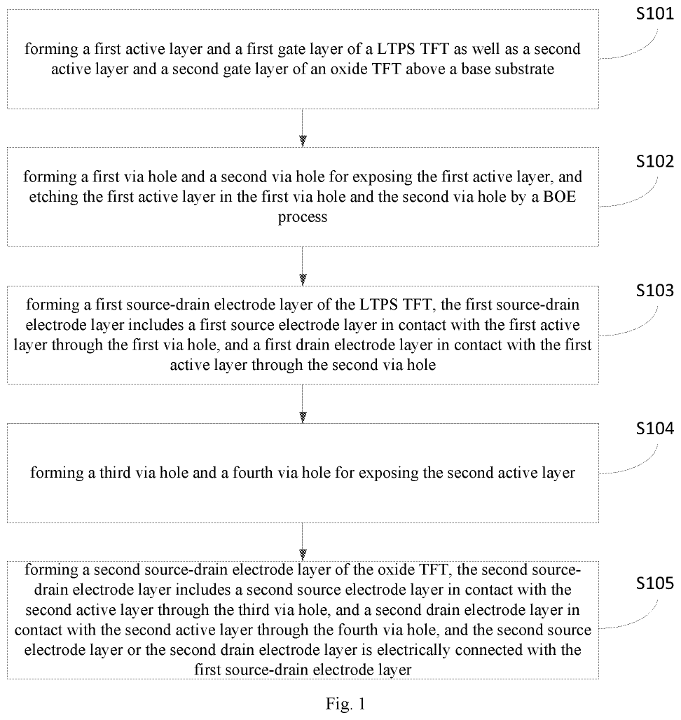

Embodiments of the present disclosure provide a method for preparing an array substrate, as shown in FIG. 1. The method includes the following operations.

S101, forming a first active layer and a first gate layer of a low temperature poly-silicon (LTPS) thin film transistor (TFT) as well as a second active layer and a second gate layer of an oxide thin film transistor (TFT) above a base substrate.

S102, forming a first via hole and a second via hole for exposing the first active layer, and etching the first active layer in the first via hole and the second via hole by a buffered oxide etch (BOE) process.

S103, forming a first source-drain electrode layer of the low temperature poly-silicon (LTPS) thin film transistor (TFT). The first source-drain electrode layer includes a first source electrode layer in contact with the first active layer through the first via hole, and a first drain electrode layer in contact with the first active layer through the second via hole.

S104, forming a third via hole and a fourth via hole for exposing the second active layer.

S105, forming a second source-drain electrode layer of the oxide thin film transistor. The second source-drain electrode layer includes a second source electrode layer in contact with the second active layer through the third via hole, and a second drain electrode layer in contact with the second active layer through the fourth via hole, and the second source electrode layer or the second drain electrode layer is electrically connected with the first source-drain electrode layer.

According to the method for preparing an array substrate, provided by embodiments of the present application, firstly, via holes for exposing the first active layer of the low temperature poly-silicon thin film transistor are formed, and a buffered oxide etch (BOE) process is performed, then, via holes for exposing the second active layer of the oxide thin film transistor are formed, i.e., the BOE process is not required after the via holes for exposing the active layer of the oxide thin film transistor are formed, and the oxide active layer may not be corroded by a BOE solution, so that the oxide active layer may be prevented from crack, and the yield of products may be increased.

Optionally, the operation S101 of forming a first active layer and a first gate layer of a low temperature poly-silicon thin film transistor as well as a second active layer and a second gate layer of an oxide thin film transistor above a base substrate includes:

sequentially forming a pattern of the first active layer, a first gate insulator (GI), a pattern of the first gate layer and a first interlayer dielectric (ILD) layer above the base substrate; and

sequentially forming a pattern of the second active layer, a pattern of a second GI, a pattern of the second gate layer and a second ILD layer above the first ILD layer.

According to the method for preparing an array substrate, provided by embodiments of the present disclosure, the first active layer and the first gate layer of the low temperature poly-silicon thin film transistor are formed firstly, and then, the second active layer and the second gate layer of the oxide thin film transistor are formed. In some embodiments, the base substrate may be, for example, a glass substrate; the first active layer may not be overlapped with the second active layer; the pattern of the second GI may cover a part of the pattern of the second active layer; and the pattern of the second GI and a pattern of an electrode layer a capacitor may be separately formed above an area of the first active layer while the pattern of the second GI and the pattern of the second gate layer are separately formed.

Optionally, the operation S102 of forming a first via hole and a second via hole for exposing the first active layer includes:

forming the first via hole and the second via hole for exposing the first active layer in the second ILD layer, the first ILD layer and the first GI.

Optionally, the first active layer includes a low temperature poly-silicon (P-Si) area and a source-drain electrode contact area. The source-drain electrode contact area includes a source electrode contact area and a drain electrode contact area separately located at two sides of the low temperature poly-silicon (P-Si) area. The source electrode contact area is exposed by the first via hole, and the drain electrode contact area is exposed by the second via hole.

Optionally, the first active layer is made of a material including indium gallium zinc oxide (IGZO).

Optionally, before the first active layer is formed, the method further includes: forming a polyimide (PI) layer, a first buffer layer and a second buffer layer above the base substrate.

Optionally, after the first ILD layer is formed, the method further includes: forming a third buffer layer on the first ILD layer.

When the third buffer is required to be formed, the operation of forming a first via hole and a second via hole for exposing the first active layer includes:

forming the first via hole and the second via hole for exposing the first active layer in the second ILD layer, the third buffer layer, the first ILD layer and the first GI.

Optionally, after the operation S103 of forming a first source-drain electrode layer, the method further includes:

depositing a protective layer (PVX) on an overall surface; and

forming a first Planarization (PLN) layer on the PVX.

Optionally, the operation S104 of forming a third via hole and a fourth via hole for exposing the second active layer includes:

forming the third via hole and the fourth via hole for exposing the second active layer in the first PLN layer, the PVX and the second ILD layer.

Optionally, when the third via hole and the fourth via hole for exposing the second active layer are formed, the method further includes:

forming a fifth via hole and a sixth via hole for exposing the first source-drain electrode layer in the PLN layer and the PVX.

According to the method for preparing an array substrate, provided by embodiments of the present disclosure, via holes for exposing the first source-drain electrode layer are formed while via holes for exposing the second active layer are formed, so that a subsequent electric connection between the first source-drain electrode layer and the second source-drain electrode layer may be performed conveniently. Moreover, since the first source-drain electrode layer is formed firstly, after the first planarization (PLN) layer is formed, the third via hole and the fourth via hole for exposing the second active layer and penetrating through the first planarization (PLN) layer, the protective layer (PVX) and the second ILD layer as well as the fifth via hole and the sixth via hole for exposing the first source-drain electrode layer and penetrating through the first planarization layer (PLN) and the protective layer (PVX) may be formed by only using one mask and an etch process, and then, the second source-drain electrode layer electrically connected with the first source-drain electrode layer is subsequently formed. However, in the related art, via holes for exposing an active layer of the oxide thin film transistor are formed firstly, next, a protective metal layer in contact with the oxide active layer is formed, then, via holes are formed in a first planarization layer, and then, via holes are formed in the protective layer, and therefore, compared with the related art, the method provided by the present disclosure has the advantages that the third via hole, the fourth via hole, the fifth via hole and the sixth via hole are formed by only using one mask and the etch process, the technical process for preparing the array substrate may also be simplified, and two masks may be saved, so that the cost is reduced.

Optionally, the operation S105 of forming a second source-drain electrode layer includes:

forming the second source electrode layer in contact with the second active layer through the third via hole, forming the second drain electrode layer in contact with the second active layer through the fourth via hole, and forming a connecting lead layer in contact with the first source-drain electrode layer through the sixth via hole. The second source electrode layer or the second drain electrode layer extends to be in contact with the first source-drain electrode layer through the fifth via hole.

It should be noted that the array substrate prepared by using the method for preparing the array substrate, provided by embodiments of the present application may be, for example, applied to an electroluminescent display product, an electroluminescent device is driven by a thin film transistor to emit light, and the connecting lead layer may be subsequently used as a connecting lead for realizing a connection between an electrode of the electroluminescent device and the thin film transistor.

According to the method for preparing an array substrate, provided by embodiments of the present application, an electric connection between the second source-drain electrode layer and the first source-drain electrode layer and an electric connection between the electroluminescent device and the first source-drain electrode layer may be realized while the second source-drain electrode layer is formed, i.e., the electric connection between the first source-drain electrode layer and the second source-drain electrode layer and the electric connection between the electroluminescent device and the first source-drain electrode layer may be realized through two electrode layers, so that the technical process for preparing the array substrate may be simplified. Compared with the related art in which the protective metal layer in contact with the second active layer is required to be formed firstly, then, the first source-drain electrode layer electrically connected with the protective metal layer and in contact with the first active layer is formed, and then, the connecting lead layer for the electric connection between the first source-drain electrode layer and the electroluminescent device is formed, the method for preparing the array substrate, provided by embodiments of the present disclosure, may save one mask, so that the cost is reduced.

According to the method for preparing an array substrate, provided by embodiments of the present disclosure, the third via hole, the fourth via hole, the fifth via hole and the sixth via hole are formed by only using one mask and an etch process, and two masks may be saved; moreover, the electric connection between the first source-drain electrode layer and the second source-drain electrode layer and the electric connection between the electroluminescent device and the first source-drain electrode layer may be realized through two electrode layers, one mask may be saved, and therefore, compared with the related art, the method for preparing the array substrate, provided by embodiments of the present application, may save three masks.

Next, the method for preparing an array substrate, provided by embodiments of the present disclosure, is illustrated with an example in which the first active layer and the first gate layer of the low temperature poly-silicon are formed firstly, and then, the second active layer and the second gate layer of the oxide thin film transistor are formed. The method for preparing the array substrate includes the following operations.

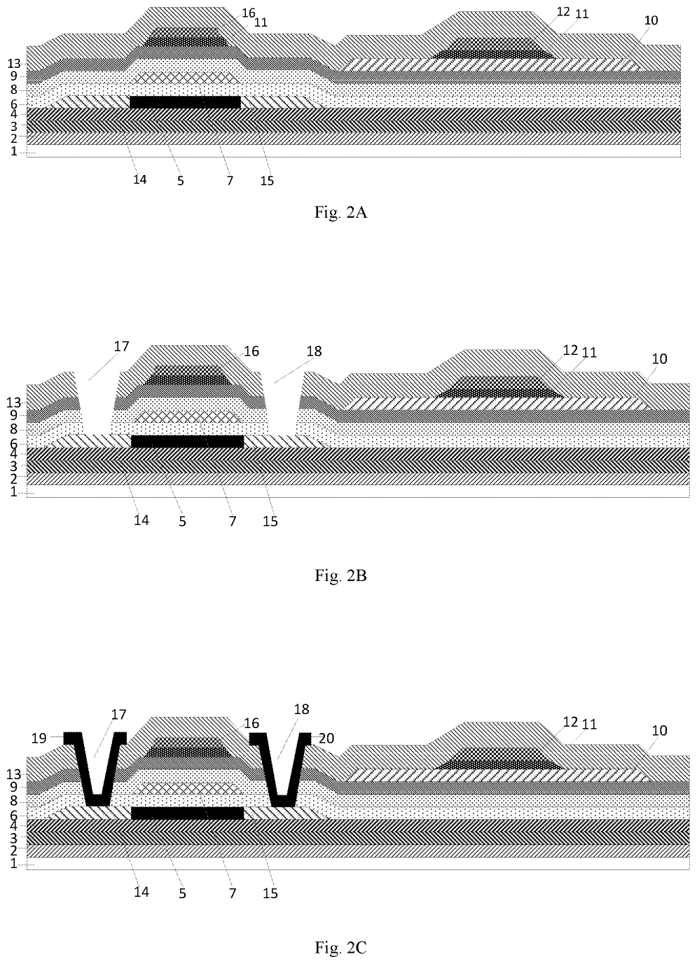

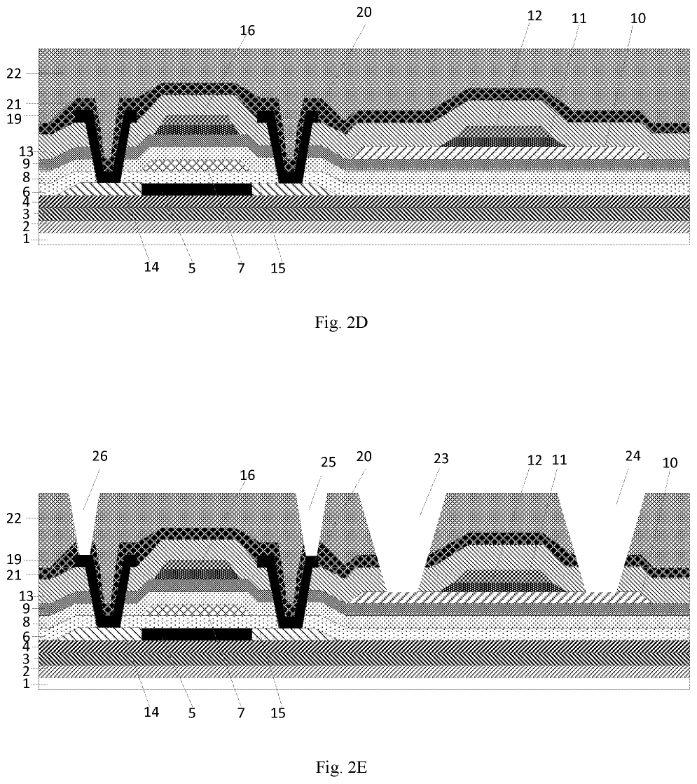

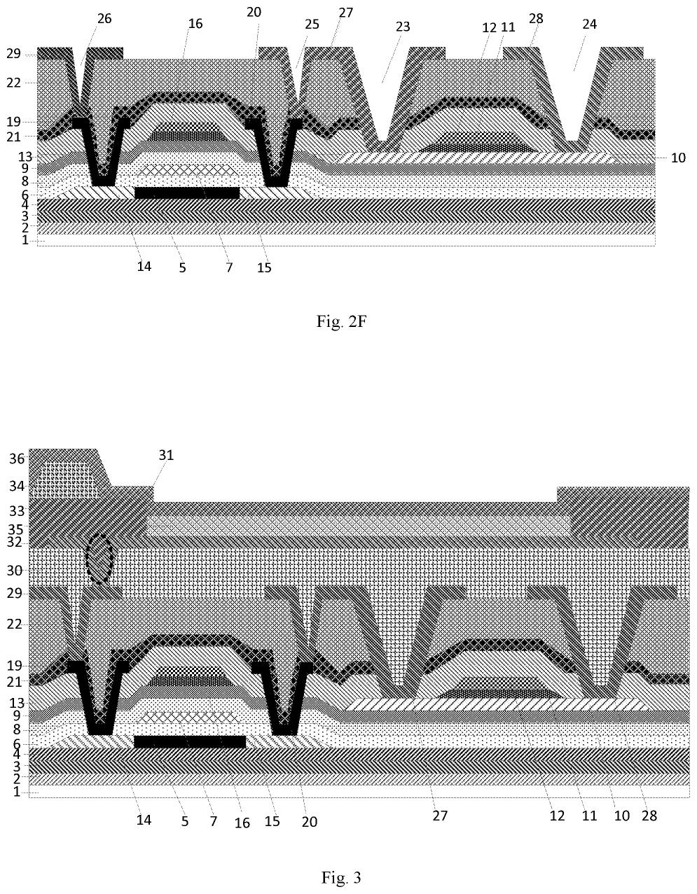

As shown in FIG. 2A, an operation is of sequentially forming a PI layer 2, a first buffer layer 3, a second buffer layer 4, a pattern of a first active layer, a first GI 6, a pattern of a first gate layer 7, a first ILD layer 8, a third buffer layer 9, a pattern of a second active layer 10, a pattern of a second GI 11, a pattern of a second gate layer 12 and a second ILD layer 13 on a glass substrate 1.

The first active layer includes a low temperature poly-silicon semiconductor area 5, a source electrode contact area 14 and a drain electrode contact area 15. The pattern of the second GI 11 is formed above an area of a low temperature poly-silicon thin film transistor while the second GI 11 of an oxide thin film transistor is formed, a pattern of an electrode layer 16 is formed above the area of the low temperature poly-silicon thin film transistor while the pattern of the second gate layer 12 of the oxide thin film transistor is formed, and the electrode layer may be used as an electrode layer of a capacitor.

As shown in FIG. 2B, operations are of forming a first via hole 17 for exposing the source electrode contact area 14 in the second ILD layer 13, the third buffer layer 9, the first ILD layer 8 and the first GI 6, and of forming a second via hole 18 for exposing the drain electrode contact area 15 in the second ILD layer 13, the third buffer layer 9, the first ILD layer 8 and the first GI 6.

As shown in FIG. 2C, operations are of forming a pattern of a first source electrode layer 19 in contact with the source electrode contact area 14 through the first via hole 17, and of forming a pattern of a first drain electrode layer 20 in contact with the drain electrode contact area 15 through the second via hole 18.

As shown in FIG. 2D, an operation is of depositing a PVX 21 on an overall surface, and forming a first PLN layer 22 on the PVX 21.

As shown in FIG. 2E, operations are of forming a third via hole 23 and a fourth via hole 24 for exposing the second active layer 10 in the first PLN layer 22, the PVX 21 and the second ILD layer 13, and of forming a fifth via hole 25 for exposing the first drain electrode layer 20 in the first PLN layer 22 and the PVX 21, and of forming a sixth via hole 26 for exposing the first source electrode layer 19 in the first PLN layer 22 and the PVX 21.

As shown in FIG. 2F, operations are of forming a pattern of a second source electrode layer 27 in contact with the second active layer 10 through the third via hole 23 and in contact with the first drain electrode layer 20 through the fifth via hole 25, of forming a pattern of a second drain electrode layer 28 in contact with the second active layer 10 through the fourth via hole 24, and of forming a pattern of a connecting lead layer 29 in contact with the first source electrode layer 19 through the sixth via hole 26.

After the second source-drain electrode layer is formed, as shown in FIG. 3, the method further includes:

forming a second planarization layer 30;

forming a seventh via hole 31 for exposing the connecting lead layer 29 in the second planarization layer 30;

forming a pattern of an anode layer 32, the anode layer 32 is in contact with the connecting lead layer 29 through the seventh via hole 31; and

sequentially forming a pixel definition layer 33, a spacer layer 34, a light emitting functional layer 35 and a cathode layer 36.

Based on the same inventive concept, embodiments of the present disclosure further provide an array substrate prepared by adopting the above-mentioned method for preparing the array substrate, provided by embodiments of the present application.

The array substrate includes a low temperature poly-silicon thin film transistor and an oxide thin film transistor electrically connected with the low temperature poly-silicon thin film transistor.

The low temperature poly-silicon thin film transistor includes a first active layer, a first gate layer and a first source-drain electrode layer. The first source-drain electrode layer includes a first source electrode layer in contact with the first active layer through a first via hole and a first drain electrode layer in contact with the first active layer through a second via hole.

The oxide thin film transistor includes a second active layer, a second gate layer and a second source-drain electrode layer. The second source-drain electrode layer includes a second source electrode layer in contact with the second active layer through a third via hole and a second drain electrode layer in contact with the second active layer through a fourth via hole, and the second source electrode layer or the second drain electrode layer is electrically connected with the first source-drain electrode layer.

The array substrate provided by embodiments of the present disclosure is prepared by adopting the above-mentioned method for preparing the array substrate. Firstly, the via holes for exposing the first active layer of the low temperature poly-silicon thin film transistor are formed, and the BOE process is performed, then, the via holes for exposing the second active layer of the oxide thin film transistor are formed, i.e., the BOE process is not required after the via holes for exposing the active layer of the oxide thin film transistor are formed, and the oxide active layer may not be corroded by a BOE solution, so that the oxide active layer may be prevented from crack, and the yield of products may be increased.

Optionally, as shown in FIG. 2F, the array substrate further includes: a glass substrate 1, a PI layer 2, a first buffer layer 3 and a second buffer layer 4; a low temperature poly-silicon thin film transistor and an oxide thin film transistor are located on the second buffer layer 4.

The low temperature poly-silicon thin film transistor includes a first active layer, a first GI 6, a first gate layer 7, a first ILD layer 8, a first source electrode layer 19 and a first drain electrode layer 20.

A third buffer layer 9 is arranged on the first ILD layer 8, and the oxide thin film transistor is located on the third buffer layer 9.

The oxide thin film transistor includes a second active layer 10, a second GI 11, a second gate layer 12, a second ILD layer13, a second source electrode layer 27 and a second drain electrode layer 28; the second active layer is not overlapped with the first active layer.

The array substrate further includes a PVX 21 located on the first source-drain electrode layer and a first PLN layer 22 located on the PVX 21.

The first active layer includes a low temperature poly-silicon semiconductor area 5, a source electrode contact area 14 and a drain electrode contact area 15. A first via hole and a second via hole penetrate through the second ILD layer 13, the third buffer layer 9, the first ILD layer 8 and the first GI 6. The first source electrode layer 19 is in contact with the source electrode contact area 14 through the first via hole, and the first drain electrode layer 20 is in contact with the drain electrode contact area 15 through the second via hole.

A third via hole 23 and a fourth via hole 24 penetrate through the PLN layer 22, the PVX 21 and the second ILD layerl3, a second source electrode layer 27 is in contact with the second active layer 10 through the third via hole 23, and a second drain electrode layer 28 is in contact with the second active layer 10 through the fourth via hole 24.

Optionally, the array substrate further includes a PVX located on the first source-drain electrode layer, a first PLN layer located on the PVX, and a connecting lead layer arranged on the same layer with the second source-drain electrode layer, the PVX and the first PLN layer include a fifth via hole and a sixth via hole for exposing the first source-drain electrode layer, the second source electrode layer or the second drain electrode layer extends to be in contact with the first source-drain electrode layer through the fifth via hole, and the connecting lead layer is in contact with the first source-drain electrode layer through the sixth via hole.

As shown in FIG. 2F, the PVX 21 and the first PLN layer 22 include a fifth via hole 25 for exposing the first drain electrode layer 20, and a sixth via hole 26 for exposing the first source electrode layer 19, the second source electrode layer 27 extends to be in contact with the first drain electrode layer 20 through the fifth via hole 25, and the connecting lead layer 29 is in contact with the first source electrode layer 19 through the sixth via hole 26.

According to the array substrate provided by embodiments of the present application, an electric connection between the second source-drain electrode layer and the first source-drain electrode layer, and an electric connection between an electroluminescent device and the first source-drain electrode layer may be realized while the second source-drain electrode layer is formed, i.e., the electric connection between the first source-drain electrode layer and the second source-drain electrode layer, and the electric connection between the electroluminescent device and the first source-drain electrode layer may be realized through two electrode layers, so that the technical process for preparing the array substrate may be simplified. Compared with the related art in which the protective metal layer in contact with the second active layer is required to be formed firstly, then, the first source-drain electrode layer electrically connected with the protective metal layer and in contact with the first active layer is formed, and then, the connecting lead layer for the electric connection between the first source-drain electrode layer and the electroluminescent device is formed, the present disclosure may save one mask, so that the cost is reduced.

Optionally, as shown in FIG. 3, the array substrate further includes an connecting lead layer 29, a second planarization layer 30, an anode layer 32, a pixel definition layer 33, a spacer layer 34, a light emitting functional layer 35 and a cathode layer 36; and the connecting lead layer 29 is arranged on the same layer with the second source-drain electrode layer and is in contact with the first source electrode layer 19 through the sixth via hole penetrating through the first PLN 22 and the PVX 21, and the anode layer 32 is in contact with the connecting lead layer 29 through the seventh via hole penetrating through the second planarization layer 30.

Embodiments of the present disclosure provide a display panel including the above-mentioned array substrate provided by embodiments of the present application.

The display panel provided by embodiments of the present application may be, for example, an electroluminescent display panel, and the electroluminescent display panel may be, for example, an organic light emitting diode display panel.

In conclusion, according to the array substrate, the preparation method thereof and the display panel provided by embodiments of the present disclosure, firstly, via holes for exposing the first active layer of the low temperature poly-silicon thin film transistor are formed, and the BOE process is performed, then, via holes for exposing the second active layer of the oxide thin film transistor are formed, i.e., the BOE process is not required after the via holes for exposing the active layer of the oxide thin film transistor are formed, and the oxide active layer may not be corroded by a BOE solution, so that the oxide active layer may be prevented from crack, and the yield of products may be increased.

Obviously, those skilled in the art can make various alterations and transformations on the present disclosure without departing from the spirit and scope of the present disclosure. In this way, if these alterations and transformations of the present disclosure fall within the scope of the claims of the present disclosure and equivalent technologies of the claims, the present disclosure is also intended to include these alterations and transformations.

What is claimed is:

1. A method for preparing an array substrate, comprising:
forming a first active layer and a first gate layer of a low temperature poly-silicon (LTPS) thin film transistor (TFT) above a base substrate;
forming a second active layer and a second gate layer of an oxide TFT above the base substrate;
forming a first via hole and a second via hole for exposing the first active layer;
etching the first active layer in the first via hole and the second via hole by a buffered oxide etch (BOE) process;
forming a first source-drain electrode layer of the LTPS TFT, wherein the first source-drain electrode layer comprises a first source electrode layer in contact with the first active layer through the first via hole, and a first drain electrode layer in contact with the first active layer through the second via hole;
forming a third via hole and a fourth via hole for exposing the second active layer; and
forming a second source-drain electrode layer of the oxide TFT, wherein the second source-drain electrode layer comprises a second source electrode layer in contact with the second active layer through the third via hole, and a second drain electrode layer in contact with the second active layer through the fourth via hole, and the second source electrode layer or the second drain electrode layer is electrically connected with the first source-drain electrode layer.

2. The method according to claim 1, wherein said forming the first active layer and the first gate layer of the LTPS TFT above a base substrate; and forming the second active layer and the second gate layer of the oxide TFT above the base substrate comprises:
sequentially forming a pattern of the first active layer, a first gate insulator, a pattern of the first gate layer and a first interlayer dielectric layer above the base substrate; and
sequentially forming a pattern of the second active layer, a pattern of a second gate insulator, a pattern of the second gate layer and a second interlayer dielectric layer above the first interlayer dielectric layer.

3. The method according to claim 2, wherein said forming the first via hole and the second via hole for exposing the first active layer comprises:
forming the first via hole and the second via hole for exposing the first active layer in the second interlayer dielectric layer, the first interlayer dielectric layer and the first gate insulator.

4. The method according to claim 2, wherein after forming the first source-drain electrode layer, the method further comprises:
depositing a protective layer on an overall surface; and
forming a first planarization layer on the protective layer.

5. The method according to claim 4, wherein said forming the third via hole and the fourth via hole for exposing the second active layer comprises:
forming the third via hole and the fourth via hole for exposing the second active layer in the first planarization layer, the protective layer and the second interlayer dielectric layer.

6. The method according to claim 5, wherein when forming the third via hole and the fourth via hole for exposing the second active layer, the method further comprises:
forming a fifth via hole and a sixth via hole for exposing the first source-drain electrode layer in the first planarization layer and the protective layer.

7. The method according to claim 6, wherein said forming the second source-drain electrode layer comprises:
forming the second source electrode layer in contact with the second active layer through the third via hole;
forming the second drain electrode layer in contact with the second active layer through the fourth via hole; and
forming a connecting lead layer in contact with the first source-drain electrode layer through the sixth via hole;
wherein the second source electrode layer or the second drain electrode layer extends to be in contact with the first source-drain electrode layer through the fifth via hole.

8. An array substrate, prepared by adopting the method for preparing the array substrate according to claim 1, wherein the array substrate comprises:
the LTPS TFT; and
the oxide TFT electrically connected with the LTPS TFT;
wherein the LTPS TFT comprises:
the first active layer;
the first gate layer; and
the first source-drain electrode layer;
wherein the first source-drain electrode layer comprises:
the first source electrode layer in contact with the first active layer through the first via hole; and
the first drain electrode layer in contact with the first active layer through the second via hole; and
the oxide TFT comprises:
the second active layer;
the second gate layer; and
the second source-drain electrode layer;
wherein the second source-drain electrode layer comprises:
the second source electrode layer in contact with the second active layer through the third via hole; and
the second drain electrode layer in contact with the second active layer through the fourth via hole;
wherein the second source electrode layer or the second drain electrode layer is electrically connected with the first source-drain electrode layer.

9. The array substrate according to claim 8, further comprising:
a protective layer on the first source-drain electrode layer;
a first planarization layer on the protective layer; and
a connecting lead layer arranged on a same layer with the second source-drain electrode layer;
wherein the protective layer and the first planarization layer comprise a fifth via hole and a sixth via hole for exposing the first source-drain electrode layer, the second source electrode layer or the second drain electrode layer extends to be in contact with the first source-drain electrode layer through the fifth via hole, and the connecting lead layer is in contact with the first source-drain electrode layer through the sixth via hole.

10. A display panel, comprising the array substrate according to claim 8, wherein the array substrate comprises:
the LTPS TFT; and
the oxide TFT electrically connected with the LTPS TFT;
wherein the LTPS TFT comprises:
the first active layer;
the first gate layer; and
the first source-drain electrode layer;
wherein the first source-drain electrode layer comprises:
the first source electrode layer in contact with the first active layer through the first via hole; and
the first drain electrode layer in contact with the first active layer through the second via hole; and
the oxide TFT comprises:
the second active layer;
the second gate layer; and
the second source-drain electrode layer;
wherein the second source-drain electrode layer comprises:
the second source electrode layer in contact with the second active layer through the third via hole; and
the second drain electrode layer in contact with the second active layer through the fourth via hole;
wherein the second source electrode layer or the second drain electrode layer is electrically connected with the first source-drain electrode layer.

11. The display panel according to claim 10, wherein the array substrate further comprises:
a protective layer on the first source-drain electrode layer;
a first planarization layer on the protective layer; and
a connecting lead layer arranged on a same layer with the second source-drain electrode layer;
wherein the protective layer and the first planarization layer comprise a fifth via hole and a sixth via hole for exposing the first source-drain electrode layer, the second source electrode layer or the second drain electrode layer extends to be in contact with the first source-drain electrode layer through the fifth via hole, and the connecting lead layer is in contact with the first source-drain electrode layer through the sixth via hole.
